(19) United States
(12) Patent Application Publication
(10) Pub. No.: US 2026/0086114 A1
(43) Pub. Date: Mar. 26, 2026

(54) SOCKET ASSEMBLIES FOR SEMICONDUCTOR DEVICES

(71) Applicant: Intel Corporation, Santa Clara, CA (US)

(72) Inventors: Brandon C. MARIN, Gilbert, AZ (US); Suddhasattwa NAD, Chandler, AZ (US); Hiroki TANAKA, Gilbert, AZ (US); Gang DUAN, Chandler, AZ (US); Srinivas PIETAMBARAM, Chandler, AZ (US); Bohan SHAN, Chandler, AZ (US); Jeremy D. ECTON, Gilbert, AZ (US)

(21) Appl. No.: 18/896,653

(22) Filed: Sep. 25, 2024

(51) Int. Cl. G01R 1/04; H05K 7/10

(52) U.S. Cl. CPC G01R 1/0483; H05K 7/1061

(57) ABSTRACT

Assemblies and methods of manufacturing assemblies that include sockets and packaged semiconductor chips are provided. The package substrates for the semiconductor chips can include cores that are formed from a solid amorphous glass layer. The package substrates can have gaps around sides and alignment pins in the assemblies.

### FIELD

Descriptions are generally related to semiconductor manufacturing, and more particular descriptions are related to assemblies comprising semiconductor packages and sockets.

### BACKGROUND

Semiconductor chips are central to intelligent devices and systems, such as personal computers, laptops, tablets, phones, servers, and other consumer and industrial products and systems. Manufacturing semiconductor chips presents a number of challenges and these challenges are amplified as devices become smaller and performance demands increase. Challenges include, for example, unwanted material interactions, precision and scaling requirements, power delivery requirements, limited failure tolerance, and material and manufacturing costs.

Semiconductor chips are typically “packaged” by attaching them to a package substrate. The package substrate can act as an interface between the semiconductor chip and other levels of interconnections, such as those for land grid array (LGA), pin grid array (PGA), or a reduced pin grid array (rPGA). A LGA, PGA, or rPGA can be used to mechanically attach and electrically couple one or more semiconductor chips to a circuit board, such as a mother board or logic board. A LGA comprises an array of lands (i.e., contacts) on a surface of a package and the array of lands can be mated to an array of pins on a socket which is mechanically attached to and electrically coupled to a circuit board. Similarly, for a PGA or a rPGA, an array of lands is mated to an array of contacts, and for a pin grid array, an array of pins on the package can be mated to an array of contacts in a socket. The rPGA has a reduced pitch between pins as compared to a PGA.

### BRIEF DESCRIPTION OF THE DRAWINGS

The figures are provided to aid in understanding the disclosure. The figures can include diagrams and illustrations of examples of structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the disclosure. Additionally, features are not necessarily illustrated relatively to scale due in part to the small sizes of some features and the desire for clarity of explanation in the figures.

FIG. 1 provides a semiconductor device assembly that includes packaged semiconductor devices and a socket.

FIG. 2 shows some exemplary designs for heat spreaders.

FIG. 3 illustrates an additional semiconductor device assembly that includes a packaged semiconductor device and a socket.

FIG. 4 illustrates a method for assembling a packaged semiconductor device with a socket.

FIG. 5 shows a method for manufacturing semiconductor package substrates.

FIG. 6 provides an example of a computing system.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation. The phrases “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, optically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following some other event or events. Other sequences of operations can also be performed according to alternative embodiments. Furthermore, additional operations may be added or removed depending on the application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Flow diagrams as illustrated herein provide examples of sequences of various process actions. The flow diagrams can indicate operations to be executed by a software or firmware routine, as well as by physical operations. Physical operations can be performed by semiconductor processing and/or testing equipment, including computer systems that run testing protocols and/or operate aspects of semiconductor manufacturing equipment and systems. Although shown in a particular sequence or order, unless otherwise specified, the order of the actions can be modified. Thus, the illustrated diagrams should be understood as examples. The processes can be performed in a different order, and some actions can be performed in parallel. Additionally, one or more actions can be omitted and not all implementations may necessarily perform all actions.

Various components described can be a means for performing the operations or functions described. Components described can include software, hardware, or a combination of these. Some components can be implemented as software modules, hardware modules, special-purpose hardware (for example, application specific hardware, application specific integrated circuits (ASICs), and digital signal processors (DSPs)), embedded controllers, and/or hardwired circuitry. Other components can be semiconductor processing and/or testing equipment that is able to perform physical operations such as, for example, lithography, probing, material deposition (for example, chemical vapor deposition, atomic layer deposition, physical vapor deposition, electrodeposition, and/or sputtering), chemical mechanical polishing, etching, pick and place operations, and assembly operations.

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described. A machine-readable storage medium includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). Instructions can be stored on the machine-readable storage medium in a non-transitory form. A communication interface includes any mechanism that interfaces to, for example, a hardwired, wireless, or optical medium to communicate to another device, such as, for example, a memory bus interface, a processor bus interface, an Internet connection, a disk controller.

Terms such as chip, die, IC (integrated circuit) chip, IC die, microelectronic chip, microelectronic die, semiconductor die, semiconductor device, and/or semiconductor chip are interchangeable and refer to a device comprising integrated circuits that can be formed in part from semiconductor materials.

Semiconductor chip manufacturing processes are sometimes divided into front end of the line (FEOL) processes and back end of the line (BEOL) processes. Electronic circuits and active and passive devices within the chip, such as for example, transistors, capacitors, resistors, and/or memory cells, are manufactured in what can be referred to as FEOL processes. Memory cells include, for example, electronic circuits for random access memory (RAM), such as static RAM (sRAM), dynamic RAM (DRAM), read only memory (ROM), non-volatile memory, and/or flash memory. FEOL processes can be, for example, complementary metal-oxide semiconductor (CMOS) processes. BEOL processes include metallization of the chip where interconnects are formed in layers and the feature size of the interconnect increases in layers nearer the surface of the semiconductor chip. Interconnects in, for example, semiconductor chips that are integrated into heterogeneous packages (such as, for example, packages that include memory and logic chips), can also include through silicon vias (TSVs) that transverse the semiconductor chip device region. Semiconductor devices that have TSVs can blur distinctions between BEOL and FEOL processes.

Semiconductor chip interconnects can be created by forming a trench or though-layer via by etching a trench or via structure into a dielectric layer and filling the trench or via with metal. Dielectric layers can comprise, for example, low-κ dielectrics, SiO₂, silicon nitride (SiN), silicon carbide (SiC), and/or silicon carbonitride (SiCN). Low-κ dielectrics include for example, fluorine-doped SiO₂, carbon-doped SiO₂, porous SiO₂, porous carbon-doped SiO₂, combinations for the foregoing, and also these materials with gas-filled gaps or bubbles. Dielectric layers that include conductive features can be interlayer dielectric (ILD) features. In general, low-κ dielectrics exhibit a dielectric constant that is less than that of SiO₂.

The terms “package,” “packaging,” “IC package,” or “chip package,” “microelectronics package,” or “semiconductor chip package” are interchangeable and generally refer to an enclosed carrier of one or more chips, in which the chips are coupled to a package substrate and encapsulated. The package substrate provides electrical interconnections between the chip(s) and other chips and/or a motherboard or other circuit board for I/O (input/output) communication and power delivery. A package with multiple chips can, for example, be a system in a package.

A package substrate generally includes dielectric layers or structures having conductive structures on, through, and/or embedded in the dielectric layers. The dielectric layers can be, for example, build-up layers. Dielectric materials include Ajinomoto build-up film (ABF), although other dielectric materials are possible. Semiconductor package substrates can have cores or be coreless. Semiconductor package substrates having cores can have dielectric layers such as build-up layers on more than one side of a core, such as on two opposite sides of a core. Cores can include through-core vias that contain a conductive material. Other structures or devices are also possible within a package substrate.

A “core,” “substrate core,” or “package core” generally refers to a layer usually embedded within a package substrate. The core can provide structure or stiffness to a package substrate. A core is an optional feature of a package substrate. The core can be a dielectric organic or inorganic material and may have conductive vias extending through the layer. The conductive vias can include a metal, for example, copper. A package core can, for example, be comprised of a glass material (such as, for example, aluminosilicate, borosilicate, alumino-borosilicate, silica, and fused silica), silicon, silicon nitride, silicon carbide, gallium nitride, or aluminum oxide. In some examples, core materials are glass-fiber reinforced organic resins such as epoxy-based resins. A further example package substrate core is FR4 (woven glass fiber reinforces epoxy). In other examples, package substrate cores are one or more solid amorphous glass layers.

In further examples of a package substrate core, the substrate core is a glass core comprising one or more solid amorphous glass layers. The glass substrate core can comprise a glass such as, for example, aluminosilicate, borosilicate, alumino-borosilicate, silica, and fused silica, that additionally optionally comprises one or more of the following: Al₂O₃, B₂O₃, MgO, CaO, SrO, BaO, SnO₂, Na₂O, K₂O, SrO, P₂O₃, ZrO₂, Li₂O, Ti, and/or Zn. In further examples of glass cores, the glass can comprise silicon and oxygen, as well as optionally any one or more of: aluminum, boron, magnesium, calcium, barium, tin, sodium, potassium, strontium, phosphorus, zirconium, lithium, titanium, and/or zinc. In some examples, a glass package substrate core comprises at least 23% silicon, at least 26% oxygen by weight. In further examples, the glass package substrate core comprises at least 23% silicon, at least 26% oxygen, and at least 5% aluminum by weight.

Additionally, examples of solid amorphous glass substrate core layers can be considered to have a rectangular prism volume. The rectangular prism volume can contain vias that have been filled with one or more different materials. A material in a via can be a conductive metal such as copper. Examples of solid amorphous glass substrate core layer(s) can have a thickness in the range of 50 μm to 1.4 mm. Additionally, the package substrate can include a multi-layer glass substrate. The package substrate in this example may be a coreless substrate. The multi-layer glass substrate can have a thickness, for example, in the range of 25 μm to 75 m. Further, glass substrate cores can have dimensions on a side of 5 mm to 600 mm. For example, the substrate core can be 5 mm by 5 mm up to 600 mm by 600 mm in two dimensions, but substrate cores do not necessarily have to have the same value in both dimensions.

A package substrate can include one or more interconnect bridges. The interconnect bridge can be partially, fully, or not embedded into the package substrate. An interconnect bridge provides interconnects between chips that are housed on the package substrate. The interconnects can provide signal I/O between the chips. Some interconnect bridges, such as ones that have conductive through-bridge vias, can also provide power to an operably connected chip. The interconnect bridge can include regions having traces that have a smaller width dimension (the smallest dimension of the trace), a smaller height dimension, and/or a length dimension than the vias and traces of the surrounding package substrate. For example, width dimensions (or smallest dimension) can be 3 μm or less and/or 10 μm or less in some regions. The interconnect bridges can also have smaller trace spacings than the surrounding package substrate. For example, trace center-to-center spacings can be 3 μm and/or less or 10 μm or less in some regions. The interconnect bridge substrate can comprise, for example, silicon, silicon-on-insulator, float glass, borosilicate glass, silicon dioxide, polymeric, one or more organic polymeric materials, ceramic, and/or a silicon nitride material. The interconnect bridge substrate can comprise, for example, one or more dielectric layers that are comprise of, silicon oxides, silicon nitride, silicon oxynitride, carbon-doped oxide, methyl silsesquioxane, hydrogen silsesquioxane, die backside film (DBF), an epoxy film, a B-stage epoxy film, other dielectric material. The interconnect bridge can also include a coreless substrate comprised of a plurality of dielectric layers. The dielectric layers can be, for example, die backside film (DBF), an epoxy film, a B-stage epoxy film, or other dielectric material. Other materials are also possible for interconnect bridge substrates. Other materials are possible.

For packages that include interconnect bridges, the pitch in the interconnect bridge region for first level interconnects (FLIs) assemblies can be less than the pitch for other regions of the FLI assembly. The pitch in the interconnect bridge region for FLIs can be, for example, less than or equal to 25 μm.

Incorporating through-bridge vias (TBVs) into interconnect bridges can enable power to be routed from a substrate package cavity to a semiconductor device attached to a package substrate. Through-bridge-vias can reduce the number of substrate routing layers required in a package substrate and can result in improved packaging yields. An interconnect bridge having TBVs can be for example, EMIB with TBVs, or EMIB-T. Depending on the bridge substrate material, a TBV may also be described as a through-silicon via (TSV) if the via traverses a region comprised of silicon, for example.

The package substrate manufacturing process is typically a build-up process that adds alternating layers of materials such as Cu and dielectric which are placed on a glass core through several thermal processes. These manufacturing processes place an enormous amount of tensile stress on a glass package substrate core, which can result in a normal stress at the edge of the panel and/or package substrate unit. The process of cutting a panel into individual package substrate units can result in fine cracks and defects along the glass substrate core edge. These cracks may be large enough to release the build up stress, resulting in package substrate failure due to core separation.

Further, during a manufacturing flow, glass-cored substrates can be handled by process equipment as many as hundreds of times. Glass can be a fragile material and can make the manufacturing process flows challenging. For example, when the glass core edge is contacted by a process tool or a LGA, PGA, or rPGA socket or other packaging assembly part, the contact increases the risk of chips and cracks that can propagate through the glass substrate core. A crack that propagates through a glass core, can cause the packaging substrate to for example, break, fracture, and/or warp so that it is no longer functional. Component losses during manufacturing can significantly increase the cost of manufacturing.

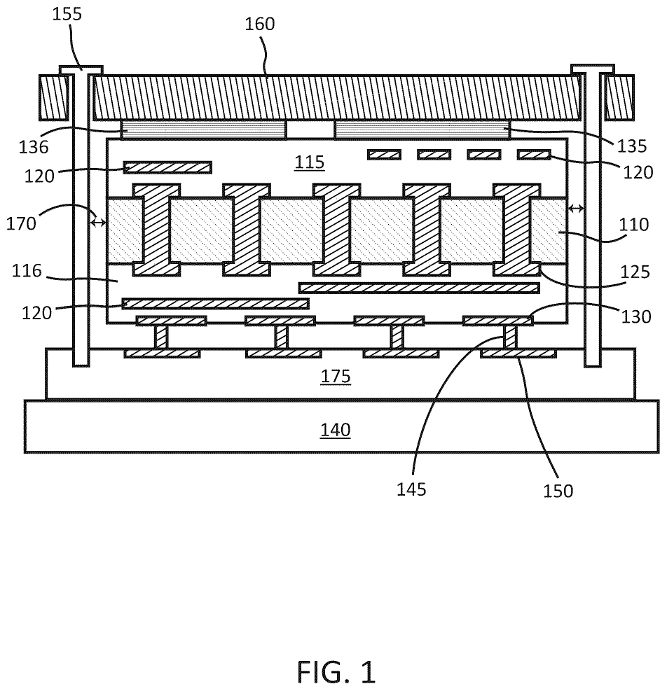

FIG. 1 illustrates a semiconductor device assembly comprising a semiconductor package and a socket. The view in FIG. 1 is a side-view in which the assembly has been sliced through along a plane so that the interior is visible. A semiconductor package includes a package substrate comprising a substrate core 110, dielectric layers 115 and 116 (individual layers are not depicted for clarity), such as build-up layers, conductive traces 120, conductive through-core vias 125, and conductive pads 130. The semiconductor package can also include conductive vias (not shown in this view) in the dielectric layers 115 and 116. Semiconductor devices 135 and 136 are electrically and operably coupled to the package substrate. Although two semiconductor devices 135 and 136 are shown, other numbers are possible, such as one, three, four, or more. The package substrate provides electrical and I/O (input/output) interconnections to the semiconductor devices 135 and 136 from the circuit board 140. Circuit board 140 can be, for example, a mother board, a logic board, a mainboard, a system board, and/or a printed circuit board. The package substrate can be electrically and communicatively coupled to the circuit board 140 through conductive features 145. Conductive features 145 can be pins, rods, bumps, solder joins, or other types of interconnections. The conductive features 145 can be comprised of a conductive material, such as a metal, layers of metals, or an alloy, such as, for example, copper, gold, aluminum, or solder.

The conductive features 145 can be initially attached to the semiconductor package substrate, such as if the socket is a PGA or a rPGA. Or the socket can comprise the conductive features 145, such as if the socket is a LGA. The socket base 175 has conductive regions 150 that can couple the circuit board 140 to the semiconductor package substrate. Conductive materials for conductive regions include metals, layers of conductive materials, and alloys, such as copper, gold, and/or aluminum. The conductive regions 150 can be shaped to form a conductive join with a conductive feature 145 or can be attached to conductive features 145 (e.g., for an LGA). The socket vase 175 can also comprise holes for attaching fasteners 155. Fasteners 155 can be helically threaded screws, or rivets. The heat spreader 160 is comprised of a thermally conductive material. The thermally conductive material can be, for example, a metal, layers of metals, or alloys of metals. The heat spreader 160 can be comprised of copper and/or aluminum, for example. The heat spreader 160 can be an integrated heat spreader (IHS).

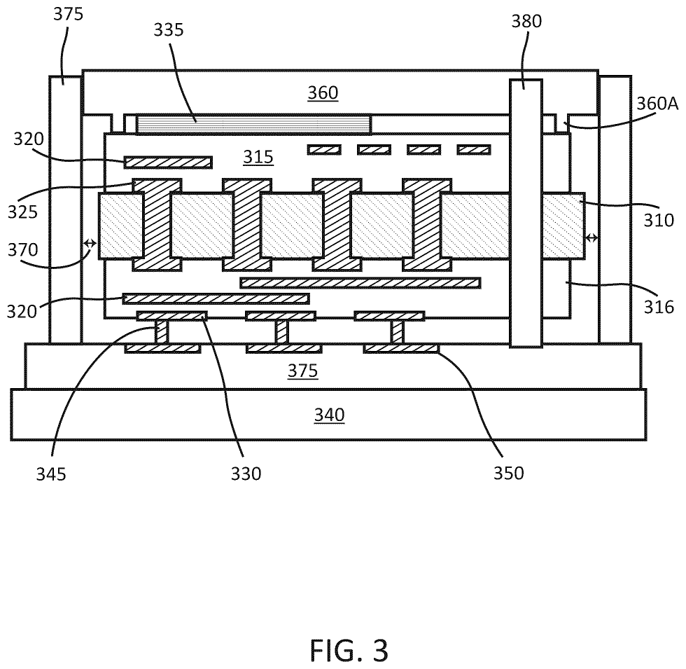

The package substrate core 110 can be comprised of any of the materials described herein for cores, such as organic or inorganic materials. The core 110 can be comprised of a glass material, and can be, for example, a glass core and/or material described herein. In FIG. 1, the semiconductor device assembly is arranged such that there is a gap 170 (or a space, or a keep-out zone) around core 110 and any surrounding parts of the socket and/or the fasteners 155. The gap 170 is illustrated by arrows. The gap 170 can allow the core 110 to not make contact with the socket or any other surrounding materials. Optionally, the socket can also include socket walls (not shown) such as the socket walls 376 illustrated for FIG. 3 that partially or completely surround four exposed edges of the package substrate so that the walls are on one to four sides of the package substrate. The optional socket walls also do not make contact with the core 110 of the package substrate. The gap 170 can be 10 μm or larger so that the smallest distance between the package core 110 and any surrounding part of the socket is 10 μm or larger. The gap 170 can optionally be different lengths on different sides of the package substrate.

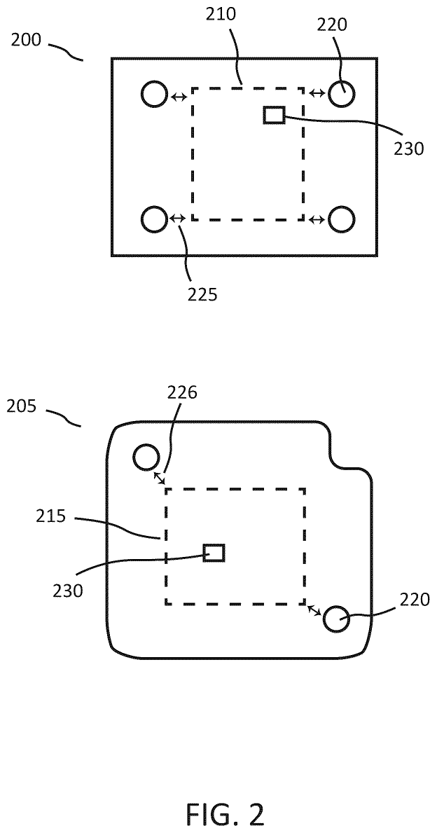

FIG. 2 illustrates footprints of exemplary heat spreaders 200 and 205, which can be the heat spreader 160 of FIG. 1. Dashed lines 210 and 215 indicate the footprints of exemplary semiconductor device packages. The footprints of exemplary heat spreaders 200 and 205 are larger than those of the semiconductor packages 210 and 215. There is a gap 225 and 226 (indicated by arrows) between the edge of the semiconductor packages 210 and 215 holes 220 into which fasteners are placed, respectively. The footprints or areas of a face of the heat spreaders 200 and 205 can be at least 1%, 2.5%, at least 5%, at least 7.5%, or at least 10% larger than the area of the semiconductor device package with which it is associated. Alternately, the footprints or areas of a face of the heat spreaders 200 and 205 can be 5-45% larger than the area of the semiconductor device package with which it is associated. Other shapes and sizes are possible for heat spreaders 200 and 205. The heat spreaders can have a different shape and still have a larger footprint than the semiconductor packages that they are assembled with. Heat spreaders 200 and 205 can also include holes 220 into which fasteners are placed, such as the fasteners 155 of FIG. 1. The numbers of holes 220 (for fasteners) can be, for example, two or four. For the assembly of FIG. 3, a heat spreader can optionally include a through-hole 230 in the area where the alignment pin 380 transverses the heat spreader. The through-holes can have other shapes, such as round, oval, square, rectangular, triangular, or multi-sided shapes having more than 4 sides.

FIG. 3 shows an additional assembly comprising a semiconductor device 335, a package substrate, and a socket. The view in FIG. 3 is a side-view in which the assembly has been sliced through along a plane so that the interior is visible. A semiconductor package includes a package substrate comprising a substrate core 310, dielectric layer regions 315 and 316 (individual layers are not depicted for clarity) which can be comprised of build-up films or layers, for example, conductive traces 320, conductive through-core vias 325, and conductive pads 330. The semiconductor package can also include conductive vias (not shown in this view) in the dielectric layer regions 315. Semiconductor device 335 is electrically and operably coupled to the package substrate. Although one semiconductor device 335 is shown, other numbers are possible, such as one, three, four, or more. The package substrate provides electrical and I/O (input/output) interconnections to the semiconductor device 335 from the circuit board 340. Circuit board 340 can be, for example, a mother board, a logic board, a mainboard, a system board, and/or a printed circuit board. The package substrate can be electrically and communicatively coupled to the circuit board 340 through conductive features 345 (e.g., electrical contacts). Conductive features 345 can be pins, rods, bumps, solder joins, or other types of interconnections. The conductive features 345 can be comprised of a conductive material, such as a metal, layers of metals, or an alloy, such as, for example, copper, gold, aluminum, or solder.

The conductive features 345 can be regions that are initially attached to the semiconductor package substrate, such as if a socket is a PGA or a rPGA. Or a socket can comprise the conductive features 345, such as if the socket is a LGA. The socket base 375 has conductive regions 350 (e.g., electrical contacts) that can couple the circuit board 340 to the semiconductor package substrate. These conductive regions 350 can be part of a socket base 375 and can be shaped to form a conductive join with a conductive feature 345 or can be attached to the conductive features 345. Conductive materials for conductive regions include metals, layers of conductive materials, and alloys, such as copper, gold, and/or aluminum. The socket can additionally comprise socket walls 376 on two to four sides of the semiconductor package substrate. The heat spreader 360 is comprised of a thermally conductive material. The thermally conductive material can be, for example, a metal, layers of metals, or alloys of metals. The heat spreader 360 can be comprised of copper and/or aluminum, for example. The heat spreader 360 can be an integrated heat spreader. Optionally, the heat spreader 360 can include protrusions 360A. Protrusions 360A can space the heat spreader 360 above the surface of the package substrate.

The package substrate core 310 can be comprised of any of the materials described herein for cores, such as organic or inorganic materials. The core 310 can be comprised of a glass material as described herein, for example. In FIG. 3, the semiconductor device assembly is arranged such that there is a gap 370 (or a space, or a keep-out zone) around core 310 and any surrounding parts of the socket and/or socket walls 376. The gap 370 is illustrated by arrows. The gap 370 can allow the core 310 to not make contact with the socket or any other surrounding materials. The socket walls 376 also do not make contact with the core 310 of the package substrate. The gap 370 can be 10 μm or larger so that the smallest distance between the package core 310 and any surrounding part of the socket is 10 μm or larger. The gap 370 can be different amounts on different sides of the package substrate.

The assembly of FIG. 3 additionally includes an alignment member 380 that transverses the package substrate. The alignment member 380 can be part of a socket and can be partially embedded in a heat spreader 360 (configuration depicted) or can transverse the heat spreader fully so that that an end of the alignment member 380 is exposed through the surface of the heat spreader 360 (configuration not shown). Similar to what is shown in FIG. 2, the heat spreader 360 footprint can be larger than the footprint of the semiconductor package substrate.

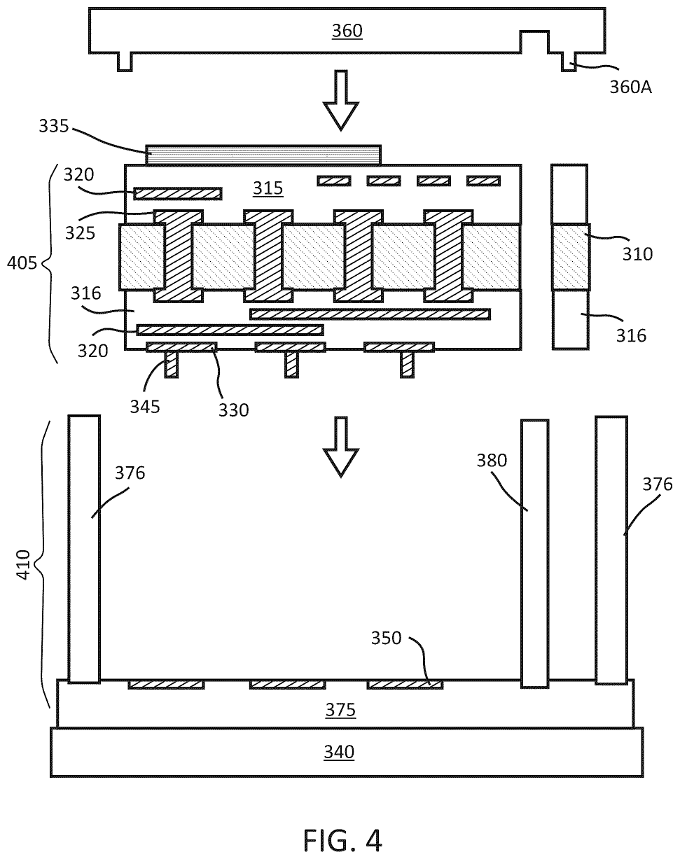

FIG. 4 shows the assembly of a packaged semiconductor device into a socket. In FIG. 4, descriptions for parts that have the same numbers as parts described with respect to FIG. 3, are the same for like-numbered parts in FIG. 4. A semiconductor package substrate 405 can be placed into a socket 410 using, for example, a pick and place robotic arm, or a chip shooter that can be used for passive component placement and surface mount technology (SMT). The heat spreader 360 can be mounted on the package substrate either before or after the package is placed into the socket 410. Retaining mechanisms (not shown), such as, for example, pins, screws, clamps, clips, lids, retention plates, or retention arms, can hold the semiconductor package in place in the socket allowing electrical connections to be maintained. The heat spreader 360 can be mounted on the package using, for example, a pick and place robotic arm, or a chip shooter that can be used for passive component placement and SMT.

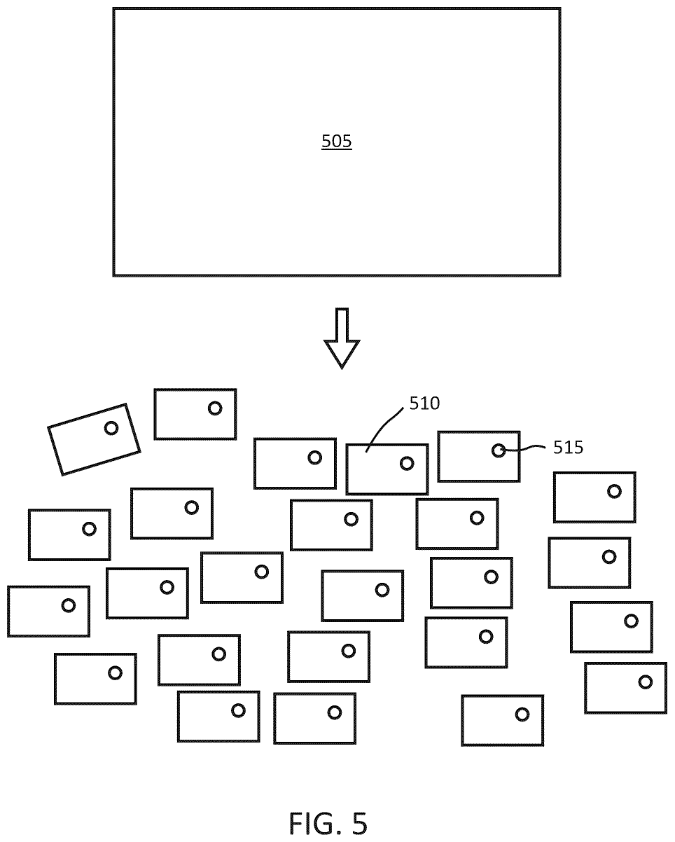

FIG. 5 illustrates a method for making a package substrate having a through-hole for an alignment feature, such as, for example, the alignment member 380 of FIGS. 3 and 4. In FIG. 5, a panel on which packaging substrates have been manufactured 505 is singulated to create individual package substrates 510. Through-holes 515 can be created at the same time. The panel can be cut into individual package substrates 510 using a singulation system comprising, for example, polymer ablation modules that can remove package materials from between the package substrates 510 and in the area of the through-hole 515 leaving a package substrate core exposed. A singulation system can also comprise a laser, or a filamentation or Bessel beam process that singulates the package substrates 510 or renders the core brittle so that it is subject to separation upon bending.

In general, circuit boards, such as circuit boards 140 and 340 can include a power supply that can control the amount of current and/or voltage going to components of the circuit board, such as the amount of current and/or voltage supplied to the semiconductor chips (such as semiconductor devices 135, 136, and 335). Power can be supplied to packaged chips through-bridges that have TBVs. The circuit board can also provide interconnections processors and other computing devices and memory, such as DRAM.

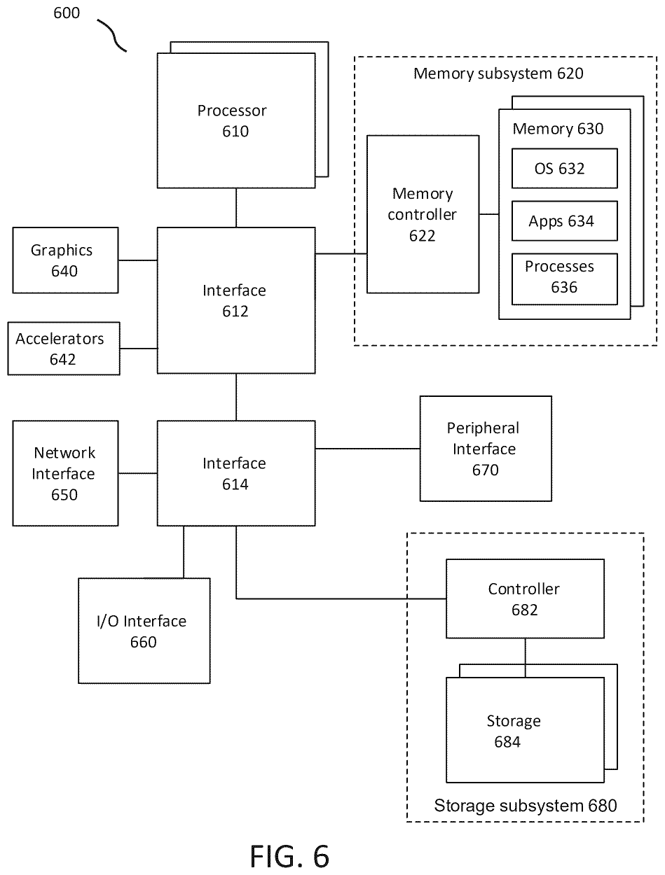

In FIGS. 1, 3, and 4 the semiconductor devices (or chips) can be, for example, any combination of microprocessors, processors, CPUs (central processing units), GPUs (graphics processing units), processing cores, system on a chips, other processing hardware, a combination of processors or processing cores, programmable general-purpose or special-purpose microprocessors, accelerators, DSPs, I/O management, programmable controllers, ASICs, programmable logic devices (PLDs), HBM, and/or other memory devices. These semiconductor chip packages can be heterogeneous packages that incorporate different types of chips into one package. The semiconductor chips can be any of the chips, for example, described herein with respect to FIG. 6. The semiconductor chip packages described herein generally can be part of various larger package structures and configurations and the foregoing examples are not meant to limit the types of assemblies that are possible.

Additional materials for heat spreaders, such as the heat spreaders, 160, 200, 205, or 360, of FIG. 1-4, include, for example, a metallic plate comprised of, for example, a thermally conductive material, such as, copper, gold, palladium, aluminum, or a combination thereof. The heat spreader can be coupled to semiconductor devices through a thermal interface material (TIM). Typically, TIMs are deformable and thermally conductive materials, and a variety of materials are possible, such as, for example, pastes, gels, greases, epoxies, silicone-based materials, and adhesives. TIMS can comprise, metallic particles. Other materials are possible for TIMs.

FIG. 6 depicts an example computing system which can comprise circuit boards comprising assemblies as described herein. Additionally, instructions for operating assembly equipment for performing one or more aspects of the process described in FIGS. 4-5 can be stored and/or run on the computing system. A computing system 600 can include more, different, or fewer features than the ones described with respect to FIG. 6.

Computing system 600 includes processor 610, which provides processing, operation management, and execution of instructions for system 600. Processor 610 can include any type of microprocessor, CPU (central processing unit), GPU (graphics processing unit), processing core, or other processing hardware to provide processing for system 600, or a combination of processors or processing cores. Processor 610 controls the overall operation of system 600, and can be or include, one or more programmable general-purpose or special-purpose microprocessors, DSPs, programmable controllers, ASICs, programmable logic devices (PLDs), or the like, or a combination of such devices.

In one example, system 600 includes interface 612 coupled to processor 610, which can represent a higher speed interface or a high throughput interface for system components needing higher bandwidth connections, such as memory subsystem 620 or graphics interface components 640, and/or accelerators 642. Interface 612 represents an interface circuit, which can be a standalone component or integrated onto a processor die. Where present, graphics interface 640 interfaces to graphics components for providing a visual display to a user of system 600. In one example, the display can include a touchscreen display.

Accelerators 642 can be a fixed function or programmable offload engine that can be accessed or used by a processor 610. For example, an accelerator among accelerators 642 can provide data compression (DC) capability, cryptography services such as public key encryption (PKE), cipher, hash/authentication capabilities, decryption, or other capabilities or services. In some cases, accelerators 642 can be integrated into a CPU socket (e.g., a connector to a motherboard (or circuit board, printed circuit board, mainboard, system board, or logic board) that includes a CPU and provides an electrical interface with the CPU). For example, accelerators 642 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 642 can provide multiple neural networks, CPUs, processor cores, general purpose graphics processing units, or graphics processing units can be made available for use by artificial intelligence (AI) or machine learning (ML) models.

Memory subsystem 620 represents the main memory of system 600 and provides storage for code to be executed by processor 610, or data values to be used in executing a routine. Memory subsystem 620 can include one or more memory devices 630 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 630 stores and hosts, among other things, operating system (OS) 632 that provides a software platform for execution of instructions in system 600, and stores and hosts applications 634 and processes 636. In one example, memory subsystem 620 includes memory controller 622, which is a memory controller to generate and issue commands to memory 630. The memory controller 622 can be a physical part of processor 610 or a physical part of interface 612. For example, memory controller 622 can be an integrated memory controller, integrated onto a circuit within processor 610.

System 600 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCIe) bus, a Hyper Transport or industry standard architecture (ISA) bus, a small computer system interface (SCSI) bus, a universal serial bus (USB), or a Firewire bus.

In one example, system 600 includes interface 614, which can be coupled to interface 612. In one example, interface 614 represents an interface circuit, which can include standalone components and integrated circuitry. In one example, user interface components or peripheral components, or both, couple to interface 614. Network interface 650 provides system 600 the ability to communicate with remote devices (e.g., servers or other computing devices) over one or more networks. Network interface 650 can include an Ethernet adapter, wireless interconnection components, cellular network interconnection components, USB, or other wired or wireless standards-based or proprietary interfaces. Network interface 650 can transmit data to a device that is in the same data center or rack or a remote device, which can include sending data stored in memory.

Some examples of network interface 650 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that can have been performed by a CPU. The IPU or DPU can include one or more memory devices.

In one example, system 600 includes one or more input/output (I/O) interface(s) 660. I/O interface 660 can include one or more interface components through which a user interacts with system 600 (e.g., audio, alphanumeric, tactile/touch, or other interfacing). Peripheral interface 670 can include additional types of hardware interfaces, such as, for example, interfaces to semiconductor fabrication equipment and/or electrostatic charge management devices.

In one example, system 600 includes storage subsystem 680. Storage subsystem 680 includes storage device(s) 684, which can be or include any conventional medium for storing data in a nonvolatile manner, such as one or more magnetic, solid state, and/or optical based disks. Storage 684 can be generically considered to be a “memory,” although memory 630 is typically the executing or operating memory to provide instructions to processor 610. Whereas storage 684 is nonvolatile, memory 630 can include volatile memory (e.g., the value or state of the data is indeterminate if power is interrupted to system 600). In one example, storage subsystem 680 includes controller 682 to interface with storage 684. In one example controller 682 is a physical part of interface 612 or processor 610 or can include circuits or logic in both processor 610 and interface 614.

A power source (not depicted) provides power to the components of system 600. More specifically, power source typically interfaces to one or multiple power supplies in system 600 to provide power to the components of system 600.

Examples of systems may be implemented in various types of computing, smart phones, tablets, personal computers, and networking equipment, such as switches, routers, racks, and blade servers such as those employed in a data center and/or server farm environment.

### EXAMPLES

An assembly can comprise: a socket wherein the socket comprises first electrical contacts, a package substrate wherein the package substrate comprises second electrical contacts and wherein the second electrical contacts are coupled to a respective ones of the first electrical contacts, a semiconductor chip wherein the semiconductor chip is electrically coupled to the package substrate, and a heat spreader wherein the heat spreader is coupled to a surface of the semiconductor chip and wherein the heat spreader has a first side and the first side has a first area, wherein the package substrate has a second side and the second side has a second area, wherein the first side is parallel to the second side, and wherein the first area is at least 2.5% larger than the second area, and wherein package substrate has third, fourth, fifth, and sixth sides, and wherein there is a gap around the third, fourth, fifth, and sixth sides and there is no contact between the third, fourth, fifth, and sixth sides and an additional surface. The socket can be a land grid array, a pin grid array, or a reduced pin grid array. The assembly can comprise fasteners wherein the fasteners traverse the heat spreader and at least partially traverse a portion of the socket. The assembly can have a first area that is 5-45% larger than the second area. The package substrate can comprise a core wherein the core comprises a solid amorphous glass layer. The package substrate can comprise a core wherein the core comprises a solid amorphous glass layer that comprises aluminosilicate, borosilicate, alumino-borosilicate, silica, or fused silica. The assembly also can comprise a circuit board wherein the circuit board is electrically coupled to the socket.

An assembly can comprise: a socket wherein the socket comprises first electrical contacts and an alignment member, a package substrate wherein the package substrate comprises second electrical contacts, wherein the second electrical contacts are coupled to a respective ones of the first electrical contacts, and wherein the alignment member transverses the package substrate, a semiconductor chip wherein the semiconductor chip is electrically coupled to the package substrate, and a heat spreader wherein the heat spreader is coupled to a surface of the semiconductor chip and wherein the heat spreader has a first side and the first side has a first area, wherein the package substrate has a second side and the second side has a second area, wherein the first side is parallel to the second side, and wherein the first area is larger than the second area, and wherein package substrate has third, fourth, fifth, and sixth sides, and wherein there is a gap around the third, fourth, fifth, and sixth sides and there is no contact between the third, fourth, fifth, and sixth sides and an additional surface. The socket can be a land grid array, a pin grid array, or a reduced pin grid array. The package substrate can comprise a core wherein the core comprises a solid amorphous glass layer. The package substrate can comprise a core wherein the core comprises a solid amorphous glass layer that comprises aluminosilicate, borosilicate, alumino-borosilicate, silica, or fused silica. The solid amorphous glass layer can additionally comprise Al₂O₃, B₂O₃, MgO, CaO, SrO, BaO, SnO₂, Na₂O, K₂O, SrO, P₂O₃, ZrO₂, Li₂O, Ti, or Zn. The assembly also can comprise a circuit board wherein the circuit board is electrically coupled to the socket. The semiconductor chip can be a processor, a central processing unit, or a graphics processing unit.

A method of manufacturing an assembly can comprise: inserting a package substrate into a socket wherein the socket comprises an alignment member, wherein the socket comprises a first side, wherein the socket comprises contacts on a face of the socket that is perpendicular to the first side, wherein the package substrate comprises a hole that traverses the package substrate, wherein the package substrate comprises second, third, fourth, and fifth sides that are parallel to the first side of the socket, and the alignment member is inserted into the hole, wherein upon insertion of the package substrate into the socket, the second, third, fourth, and fifth sides do not make contract with the first side of the socket, and placing a heat spreader on a surface of the package substrate wherein the heat spreader extends beyond the second, third, fourth, and fifth sides of the package substrate. The socket can comprise sixth, seventh, and eighth sides and the sixth, seventh, and eighth sides do not make contact with the second, third, fourth, and fifth sides of the package substrate upon insertion of the package substrate into the socket. The socket can be a land grid array, a pin grid array, or a reduced pin grid array. The method also can comprise activating a retaining mechanism to hold the package substrate in the socket. The package substrate can comprise a core and the core comprises a solid amorphous glass layer. The method package substrate can have a semiconductor device that is electrically coupled to the package substrate.

Besides what is described herein, various modifications can be made to what is disclosed and implementations without departing from their scope. Therefore, the illustrations and examples herein should be construed in an illustrative, and not a restrictive sense.

What is claimed is:

1. An assembly comprising:
a socket wherein the socket comprises first electrical contacts;
a package substrate wherein the package substrate comprises second electrical contacts and wherein the second electrical contacts are coupled to a respective ones of the first electrical contacts;
a semiconductor chip wherein the semiconductor chip is electrically coupled to the package substrate; and
a heat spreader wherein the heat spreader is coupled to a surface of the semiconductor chip and wherein the heat spreader has a first side and the first side has a first area, wherein the package substrate has a second side and the second side has a second area, wherein the first side is parallel to the second side, and wherein the first area is at least 2.5% larger than the second area; and
wherein package substrate has third, fourth, fifth, and sixth sides, and wherein there is a gap around the third, fourth, fifth, and sixth sides and there is no contact between the third, fourth, fifth, and sixth sides and an additional surface.

2. The assembly of claim 1, wherein the socket is a land grid array, a pin grid array, or a reduced pin grid array.

3. The assembly of claim 1 also comprising fasteners wherein the fasteners traverse the heat spreader and at least partially traverse a portion of the socket.

4. The assembly of claim 1 wherein first area is 5-45% larger than the second area.

5. The assembly of claim 1 wherein the package substrate comprises a core and the core comprises a solid amorphous glass layer.

6. The assembly of claim 1 wherein the package substrate comprises a core and the core comprises a solid amorphous glass layer that comprises aluminosilicate, borosilicate, alumino-borosilicate, silica, or fused silica.

7. The assembly of claim 1 also comprising a circuit board wherein the circuit board is electrically coupled to the socket.

8. An assembly comprising:
a socket wherein the socket comprises first electrical contacts and an alignment member;
a package substrate wherein the package substrate comprises second electrical contacts, wherein the second electrical contacts are coupled to a respective ones of the first electrical contacts, and wherein the alignment member transverses the package substrate;
a semiconductor chip wherein the semiconductor chip is electrically coupled to the package substrate; and
a heat spreader wherein the heat spreader is coupled to a surface of the semiconductor chip and wherein the heat spreader has a first side and the first side has a first area, wherein the package substrate has a second side and the second side has a second area, wherein the first side is parallel to the second side, and wherein the first area is larger than the second area; and
wherein package substrate has third, fourth, fifth, and sixth sides, and wherein there is a gap around the third, fourth, fifth, and sixth sides and there is no contact between the third, fourth, fifth, and sixth sides and an additional surface.

9. The assembly of claim 8 wherein the socket is a land grid array, a pin grid array, or a reduced pin grid array.

10. The assembly of claim 8 wherein the package substrate comprises a core and the core comprises a solid amorphous glass layer.

11. The assembly of claim 8 wherein the package substrate comprises a core and the core comprises a solid amorphous glass layer that comprises aluminosilicate, borosilicate, alumino-borosilicate, silica, or fused silica.

12. The assembly of claim 11 wherein the solid amorphous glass layer additionally comprises Al₂O₃, B₂O₃, MgO, CaO, SrO, BaO, SnO₂, Na₂O, K₂O, SrO, P₂O₃, ZrO₂, Li₂O, Ti, or Zn.

13. The assembly of claim 8 also comprising a circuit board wherein the circuit board is electrically coupled to the socket.

14. The assembly of claim 8 wherein the semiconductor chip is a processor, a central processing unit, or a graphics processing unit.

15. A method of manufacturing an assembly comprising:
inserting a package substrate into a socket wherein the socket comprises an alignment member, wherein the socket comprises a first side, wherein the socket comprises contacts on a face of the socket that is perpendicular to the first side, wherein the package substrate comprises a hole that traverses the package substrate, wherein the package substrate comprises second, third, fourth, and fifth sides that are parallel to the first side of the socket, and the alignment member is inserted into the hole;
wherein upon insertion of the package substrate into the socket, the second, third, fourth, and fifth sides do not make contract with the first side of the socket; and
placing a heat spreader on a surface of the package substrate wherein the heat spreader extends beyond the second, third, fourth, and fifth sides of the package substrate.

16. The method of claim 15 wherein the socket comprises sixth, seventh, and eighth sides and the sixth, seventh, and eighth sides do not make contact with the second, third, fourth, and fifth sides of the package substrate upon insertion of the package substrate into the socket.

17. The method of claim 15 wherein the socket is a land grid array, a pin grid array, or a reduced pin grid array.

18. The method of claim 15 also comprising activating a retaining mechanism to hold the package substrate in the socket.

19. The method of claim 15 wherein the package substrate comprises a core and the core comprises a solid amorphous glass layer.

20. The method of claim 15 wherein the package substrate has a semiconductor device that is electrically coupled to the package substrate.
